(19) United States
(12) Patent Application Publication
(10) Pub. No.: US 2008/0197430 A1
(43) Pub. Date: Aug. 21, 2008

(54) Biochemical Semiconductor Chip Laboratory Comprising A Coupled Address And Control Chip And Method For Producing The Same

(76) Inventors: Robert Aigner, Ocoee, FL (US); Ralf Brederlow, Poing (DE); Lude Elbrecht, Munchen (DE); Heinrich Heiss, Munchen (DE); Stephan Marksteiner, Neubiberg (DE); Werner Simburger, Haar (DE); Roland Thewes, Grobenzell (DE); Hans-Jorg Timme, Ottobrunn (DE)

Correspondence Address: HARNESS, DICKEY & PIERCE, P.L.C., P.O.BOX 8910, RESTON, VA, 20195, US

(21) Appl. No.: 11/791,963

(22) PCT Filed: Nov. 29, 2005
(86) PCT No.: PCT/EP2005/056311

§ 371 Date: Dec. 10, 2007

(30) Foreign Application Priority Data
Dec. 1, 2004 (DE) 10 2004 058 064.2

(51) Int. Cl. H01L 27/00; H01L 21/00; G01N 29/00

(52) U.S. Cl. 257/414; 438/49; 73/580; 257/E21.001; 257/E27.001

(57) ABSTRACT

A biochemical semiconductor chip laboratory is disclosed including a coupled address and control chip for biochemical analyses and a method for producing the same. In at least one embodiment the semiconductor chip laboratory has a semiconductor sensor chip, which provides numerous analytical positions for biochemical samples in a matrix. The sensor chip is located on the address and control chip and the analytical positions are in electric contact with a printed contact structure on the upper face of the address and control chip via low-resistance through-platings through the semiconductor substrate of the semiconductor chip.

### PRIORITY STATEMENT

This application is the national phase under 35 U.S.C. § 371 of PCT International Application No. PCT/EP2005/056311 which has an International filing date of Nov. 29, 2005, which designated the United States of America and which claims priority on German Patent Application number 10 2004 058 064.2 filed Dec. 1, 2004, the entire contents of which are hereby incorporated herein by reference.

1. Field

Embodiments of the invention generally relate to a biochemical semiconductor chip laboratory. For example, they may relate to one including a coupled addressing and control chip, for example for pharmaceutical analyses, and/or a method for producing the same implementation of the analyses.

2. Background

The document DE 199 44 452 discloses a position detector with surface acoustic waves, wherein the position of a sample on a surface is determined with the aid of the surface acoustic wave detector and a variable-frequency surface acoustic wave transformer.

Furthermore, the document DE 10 2004 025 269 discloses biocells on a biosubstrate, wherein the chip substrate has a glass plate having a multiplicity of analysis positions at which biochemical samples are deposited which are investigated using an analysis liquid, wherein optical fluorescence phenomena indicate a docking of chain molecules in the analysis solution to the molecules on the analysis positions. Such a “laboratory in miniature format” has analysis islands that are coated with different genetic substances, and afterward the reactions of these up to 400 different genetic samples in the laboratory in miniature format and their reactions to an active substance or an analysis substance are examined.

With such laboratories in miniature format it is possible to employ investigations of inflammations, of various types of cancer, of neurological disorders, of multiple sclerosis in the context of pharmaceutical or diagnostic investigations. Moreover, such laboratories in miniature format can be used in foodstuff research, paternal analysis, phorensics, predisposition diagnosis or else for higher resistance investigations. Optical detection mechanisms, such as fluorescence, are used for this purpose nowadays. For further applications in the area of molecular investigations of DNA hybrids or proteins with antibody reactions, optical detection mechanisms are often inadequate both in terms of their resolution and with regard to their analysis parameters. What is more, a disadvantage of these laboratories in miniature format is that they are not compatible with conventional semiconductor fabrication techniques.

### SUMMARY

At least one embodiment of the invention specifies a biochemical semiconductor chip laboratory comprising a coupled addressing and control chip, for example for pharmaceutical analyses and/or a method for producing the same in which semiconductor fabrication techniques are used and a multiplicity of different biochemical samples can be positioned and detected and corresponding electronically detected signals can be characterized and evaluated. In at least one embodiment, the intention is that these semiconductor chip laboratories comprising a coupled addressing and control chip can be used for DNA analyses (deoxyribonucleic acid analyses) or RNA analyses (ribonucleic acid analyses).

At least one embodiment of the invention provides a biochemical semiconductor chip laboratory comprising a coupled addressing and control chip for biochemical, in particular pharmaceutical analyses. In this case, a semiconductor sensor chip has a multiplicity of analysis positions for biochemical samples which are arranged in a matrix. The semiconductor chip sensor is arranged on the addressing and control chip, wherein the analysis positions are electrically connected to an interconnect structure on the top side of the addressing and control chip via low-resistance through contacts through the semiconductor chip substrate of the semiconductor sensor chip.

This semiconductor chip laboratory has the advantage that both the semiconductor sensor chip and the addressing and control chip can be produced by way of semiconductor-technological fabrication steps. However, the semiconductor sensor chip has been modified to the effect that it is connected to the addressing and control chip via its rear side. For this purpose, the contact-connection is effected on the rear side of said semiconductor sensor chip and is electrically connected to the top side, which carries the analysis positions, via a low-resistance through contact.

The through contacts can advantageously already be produced at the semiconductor wafer level either by etching passages into the semiconductor wafer, which are subsequently filled with metal, such as copper, or by performing a high doping of the semiconductor substrate in the regions of the silicon wafer that are provided for the through contact. In this case, a complementary doping can additionally be effected in the vicinity of the through contact for the purpose of insulating the through contacts from the silicon substrate. This can also be followed by thinning of the wafer by grinding from the rear side in order, on the one hand, to uncover the through contacts and, on the other hand, to thin the semiconductor wafer.

In this case, the biochemical sensor principle is based on an FBAR resonator (film bulk acoustic wave resonator), which can detect mass differences, density changes and viscosity variations on a biochemically prepared surface. The principle of this biochemical sensor analysis is explained in more detail in the subsequent figures. In principle, molecules to be analyzed are fixed on the surface of the semiconductor sensor of the semiconductor chip laboratory in the analysis positions and are exposed to a liquid having analysis molecules. Depending on the chemical structure of the analysis molecules, the latter are or are not docked chemically to the sample molecules. A change in the mass, the density and/or the viscosity on the sensor surface results from this and can be detected as a change in the oscillation frequency of the FBAR resonator.

A further advantage of the semiconductor chip laboratory according to at least one embodiment of the invention is that it operates at resonant oscillation frequencies of the order of magnitude of gigahertz, in contrast to the abovementioned laboratories in miniature format which are based on glass plates and which operate in the megahertz range. The increased resonant frequency is associated with a significantly increased resolution. What is more, it is easily possible to produce a sensor matrix composed of FBAR resonators since said resonators can be fabricated by way of standard silicon techniques. With a semiconductor chip laboratory of this type, a higher throughput for pharmaceutical experiments is also achieved, and, primarily, a fully automated semiconductor chip laboratory is realized by the combination with an addressing and control chip. Preferably, the semiconductor sensor chip converts mass and density changes of biochemical samples into resonant frequency changes, so that the latter can be detected as electrical signals by the assigned addressing and control chip.

In a further example embodiment of the invention, the FBAR resonator structures have piezoelectric elements having FBAR resonant frequencies in the gigahertz range. Since, as mentioned above, the resolution of the sensors rises quadratically with the oscillation frequency, an increase in the frequency is greatly advantageous, in particular for high-resolution systems. The piezoelectric elements have a layer made of aluminum nitride that is arranged between two metal electrodes in sandwich-like fashion. In this case, the top electrode is covered with a biochemical coupling layer made of silicon nitride. In this case, the resonant frequency of the resonator is determined by the thickness of the piezoelectric layer made of silicon nitride, and additionally by the mass of the electrode.

In a further example embodiment of the invention, a plurality of acoustic reflector layers for BAW waves (bulk acoustic waves) are arranged below the piezoelectric elements. Said acoustic reflector layers alternately have layers of high impedance and layers of low impedance, the layers of low impedance preferably being constructed as acoustic mirrors made of tungsten. The layers of low impedance preferably comprise silicon dioxide if the analysis positions are arranged on a silicon semiconductor substrate. The acoustic reflector layers are intended to decouple the substrate from the vibrations of the piezoelectric elements.

In a further example embodiment of the invention, a cavity for the decoupling of BAW waves is arranged between the piezoelectric elements and the semiconductor substrate.

By way of a cavity, it is likewise possible for the vibration of the FBAR resonators to be decoupled from the substrate.

It is furthermore provided that the addressing and control chip has circuits based on complementary MOS transistors for taking up and for evaluating resonant frequency changes in the gigahertz range. Such CMOS semiconductor chips can serve as basic chips for the semiconductor chip laboratory, in which case, as a result of the placement of the semiconductor sensor chip onto the top side of the CMOS semiconductor chip, a significant reduction of the distance between active components and sensors or actuators of the semiconductor sensor chip with the improved resolution associated therewith is advantageous. Moreover, there is the possibility of connecting a large matrix with a multiplicity of analysis positions of the semiconductor sensor chip to the addressing and control chip in low-resistance fashion by surface mounting.

What are crucial for the close coupling of CMOS semiconductor chip to the sensor chip are the low-resistance through contacts of each of the analysis positions from the top side of the semiconductor sensor chip through the substrate of the semiconductor sensor chip as far as the top side of the addressing and control chip with its interconnect structure. For this purpose, according to a further embodiment of the invention, the low-resistance through contacts have highly doped passage regions through the thickness of the semiconductor substrate from the top side to the rear side of the semiconductor sensor chip.

The passage regions can already be indiffused or ion-implanted on the semiconductor wafer by way of correspondingly high dopings at the particular passage locations for the through contacts. The highly doped passage regions can be surrounded by complementarily doped regions of the semiconductor substrate. If the conduction type of the highly doped through contact is the same conduction type as the conduction type of the lightly doped semiconductor substrate, then a region having complementary doping can be provided which surrounds the region of the through contact in order to ensure that there are no feedbacks via the weakly doped semiconductor substrate.

In a further embodiment of the invention, the low-resistance through contacts have a metallically conductive material arranged in the passages from the top side to the underside of the semiconductor substrate in the analysis positions. For this purpose, corresponding passages can be introduced into the semiconductor wafer, the walls of which passages are firstly coated with an insulation layer, preferably made of SiO₂. The passages are subsequently filled galvanically with copper or other metals.

A method, in at least one embodiment, for producing a biochemical semiconductor chip laboratory comprising a semiconductor sensor chip and an addressing and control chip has the following method steps. The first step involves providing low-resistance through contacts from the top side of a semiconductor substrate to the underside of the semiconductor substrate in correspondingly provided analysis positions of a semiconductor sensor chip or a semiconductor wafer. This is followed by applying a multiplicity of analysis positions for biochemical samples in a matrix on the semiconductor substrate with formation of a semiconductor sensor chip.

An addressing and control chip with interconnect structure and with contact pads for the connection of the through contacts of a semiconductor sensor chip on the surface of the addressing and control chip is produced independently of the production of the semiconductor sensor chip. As soon as the two semiconductor chip components of the semiconductor chip laboratory have been produced in corresponding semiconductor-technology fabrication installations, the semiconductor sensor chip is applied by its surface-mountable low-resistance through contacts onto the contact pads of the interconnect structure of the addressing and control chip. The semiconductor chip laboratory produced is subsequently embedded into a plastic housing composition whilst leaving free the analysis positions of the semiconductor sensor chip.

This method, in at least one embodiment, has the advantage that a semiconductor chip laboratory arises in which the integrated circuits for addressing and control are situated in direct proximity to the sensors and actuators. Furthermore, the method, in at least one embodiment, enables a simple and yield-optimized realization of such semiconductor chip laboratories.

A method for biochemical analysis using the semiconductor chip laboratory according to at least one embodiment has the following method steps. Firstly, biochemical samples are applied to the analysis positions of the semiconductor chip laboratory. Afterward, a first resonant frequency is determined in the analysis positions, and said first resonant frequency is stored under the addresses of the addressing and control chip.

Afterward, an analysis solution is applied to the biochemical samples fixed on the analysis positions. During the chemical reaction in the form of docking of molecules from the analysis solution to the biochemical samples, there is a change in the density and the mass and possibly also the viscosities in the individual analysis positions after the analysis solution has been removed with these reaction products being left behind. Afterward, a second resonant frequency is determined in the analysis positions and said second resonant frequency is once again stored under the addresses of the addressing and control chip. A final step involves forming the differences between the first and second resonant frequencies determined in the addressing and control chip unit and evaluating the difference between the resonant frequencies in order to determine the changes in the mass and/or the density and/or the viscosity of the biochemical samples.

With this method, the optical DNA investigations that have been customary heretofore can advantageously be performed by automated electronic semiconductor chip laboratories, such that an optimized and objective statement about the docking of different analysis molecules to the corresponding DNA samples can be effected without the complicated optical investigations. This also ensures that the analysis speed can be increased by a multiple in comparison with the conventional DNA analyses, whereby a higher throughput in the laboratories likewise becomes possible. In a further example implementation of the method, comparison and/or calibration samples are deposited on the analysis positions in order to enable standardization.

### BRIEF DESCRIPTION OF THE DRAWINGS

Example embodiments of the invention will now be explained in more detail with reference to the accompanying figures.

FIG. 1 shows a schematic cross section through a semiconductor sensor chip in accordance with a first embodiment of the invention in the region of an analysis position;

FIG. 2 shows a schematic cross section through a semiconductor sensor chip in accordance with a second embodiment of the invention in the region of an analysis position;

FIG. 3 shows a schematic cross section through a semiconductor sensor chip in accordance with a third embodiment of the invention in the region of an analysis position;

FIG. 4 shows a schematic plan view of a semiconductor sensor chip in the region of an analysis position;

FIG. 5 shows a schematic cross section of the semiconductor sensor chip in accordance with FIG. 1 in the region of the piezoelectric element;

FIG. 6 shows a schematic cross section of the semiconductor sensor chip of a fourth embodiment of the invention in the region of an analysis position;

FIG. 7 shows a schematic cross section of the semiconductor sensor chip of a fifth embodiment of the invention in the region of an analysis position;

FIG. 8 shows a schematic cross section through a semiconductor sensor chip prior to connection to an addressing and control chip to form a semiconductor chip laboratory;

FIG. 9 shows a perspective basic schematic diagram of a semiconductor chip laboratory of a first embodiment of the invention;

FIG. 10 shows a schematic cross section through an analysis position with applied analysis solution;

FIG. 11 shows a basic schematic diagram with docking of a DNA indicator to a DNA sample;

FIG. 12 shows a basic schematic diagram of provision of a DNA sample to be analyzed;

FIG. 13 shows a basic schematic diagram of docking of a DNA indicator on an analysis position to a DNA sample;

FIG. 14 shows a basic schematic diagram of DNA indicators docked to DNA samples on an analysis position;

FIG. 15 shows a basic schematic diagram of provision of a DNA sample to be analyzed;

FIG. 16 shows a basic schematic diagram of repulsion of DNA indicators on an analysis position;

FIG. 17 shows a basic schematic diagram of a non-marked DNA sample on an analysis position;

FIG. 18 shows a basic schematic diagram of a semiconductor chip laboratory after taking up a biochemical sample with circuits of the addressing and control chip;

FIG. 19 shows a basic schematic diagram of a semiconductor chip laboratory after docking of analysis molecules to biochemical molecules of the sample;

FIG. 20 shows a basic schematic diagram of application of an analysis solution to an analysis position;

FIG. 21 shows a basic schematic diagram of application of an analysis solution to a plurality of analysis positions;

FIG. 22 shows a basic schematic diagram of a changeover from one analysis position to the next analysis position.

### DETAILED DESCRIPTION OF THE EXAMPLE EMBODIMENTS

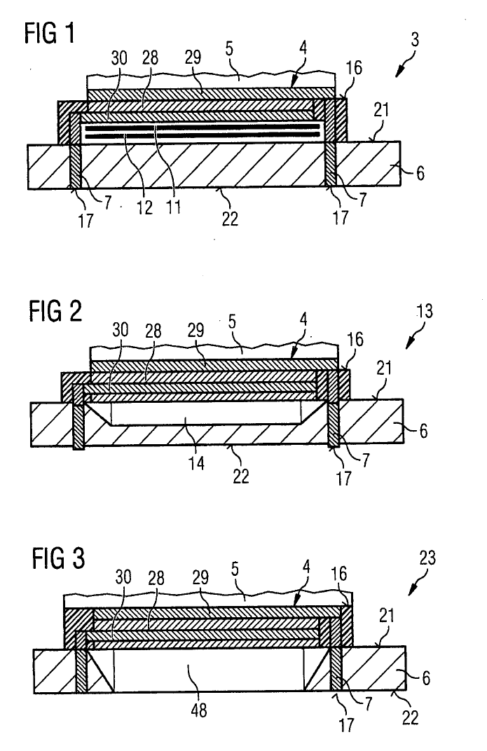

FIG. 1 shows a schematic cross section through a semiconductor sensor chip 3 in accordance with a first embodiment of the invention in the region of an analysis position 4. In the analysis position 4, the semiconductor sensor chip 3 has on its semiconductor substrate 6 a piezoelectric element 28 in the form of a layer which includes aluminum nitride and which is enclosed by a top electrode 29 and a bottom electrode 30 in sandwich-like fashion. A biochemical sample 5 is situated on the top electrode 29. The electrodes 29 and 30 are connected to the rear side 22 of the semiconductor substrate 6 via low-resistance through contacts 7. In this first embodiment of the semiconductor sensor chip 3, the semiconductor sensor chip 3 has two reflector layers 11 and 12 made of tungsten, which are insulated from one another by silicon dioxide layers and serve as acoustic reflectors in order to decouple the top side 21 of the semiconductor substrate 6 from the vibrations of the semiconductor sensor chip 3 in the gigahertz range.

FIG. 2 shows a schematic cross section through a semiconductor chip 13 in accordance with a second embodiment of the invention in the region of an analysis position 4. Components having the same functions as in FIG. 1 are identified by identical reference symbols and are not discussed separately. The second version has through contacts 7 to the rear side 22 of the semiconductor substrate 6 in order to open up the possibility of fitting the semiconductor sensor chip 13 onto an addressing and control chip (not shown here) by surface mounting and electrically connecting it to an interconnect structure of said addressing and control chip via the through contacts 7. In this second embodiment of the invention, the mechanical decoupling between the piezoelectric element 28 and the semiconductor substrate 6 arranged underneath is not achieved by means of reflector layers, but rather by means of a cavity 14 arranged between the semiconductor substrate 6 and the piezoelectric element 28.

FIG. 3 shows a schematic cross section through a semiconductor sensor chip 23 in accordance with a third embodiment of the invention in the region of an analysis position 4. Components having the same functions as in the previous figures are identified by identical reference symbols and are not discussed separately. What is characteristic in the third embodiment, too, is that through contacts 7 connect the top and bottom electrodes 29 and 30 of the piezoelectric element 28 to the rear side 22 of the semiconductor substrate 6 via through contacts 7, so that the electrodes 29 and 30 of the piezoelectric element 28 can be controlled from the rear side 22 and it is possible to conduct signals on the rear side 22 of the semiconductor substrate 6 to the circuits of the addressing and control chip (not shown). The decoupling of the semiconductor substrate 6 from the piezoelectric element 28 is achieved by way of a cutout 48 in the semiconductor substrate 6.

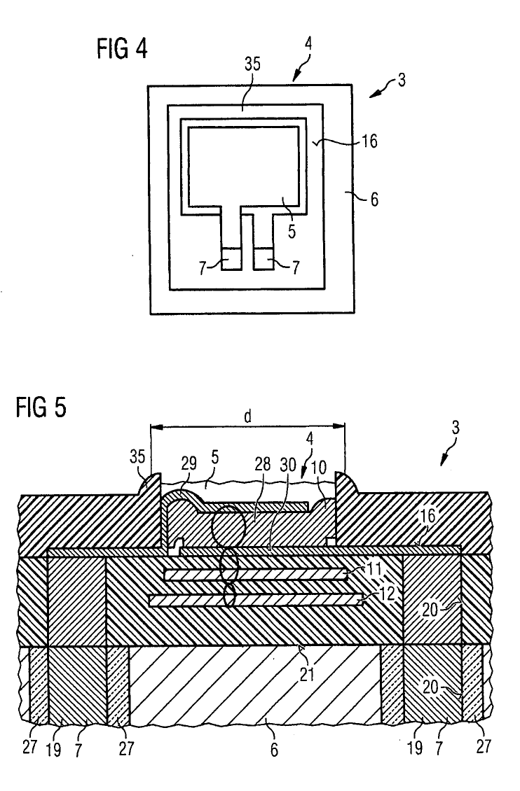

FIG. 4 shows a schematic plan view of a semiconductor sensor chip 3 in the region of an analysis position 4. The analysis position 4 has a larger area than the biochemical sample 5 since compartmentalizing elements 35 in the form of a plastic frame delimit the biochemical sample 5. The semiconductor substrate 6 with its through contacts 7 can also be formed in multilayer fashion and have wiring layers.

The piezoelectric element includes the abovementioned aluminum nitride layer to the greatest possible extent. The top electrode of the piezoelectric element and the bottom electrode of the piezoelectric element have metals, preferably copper, wherein the top metal electrode is provided with a silicon nitride layer in order to protect it from corrosion by the biochemical sample 5 to be investigated and to enable fixing of macromolecules on the top metal electrode. The reflector layers 11 and 12 of the first embodiment of the invention in accordance with FIG. 1 are arranged at a distance of approximately λ/4 and form an alternation of layers with low impedance and with high impedance. The through-plating is divided into two in the three embodiments of FIGS. 1 to 3 and has plated-through holes through active layers in an upper region and plated-through holes through the semiconductor substrate 6 in a lower region.

FIG. 5 shows a schematic cross section of the semiconductor sensor chip 3 in accordance with FIG. 1 in the region of the piezoelectric element 28. The piezoelectric element 28 made of aluminum nitride is arranged as a layer between two metal electrodes 29 and 30 in sandwich-like fashion and has a diameter d of about 150 μm in this embodiment of the invention. In this embodiment of the invention, the top electrode 29 is coated with a layer of silicon nitride that couples the biochemical sample 5. The resonant frequency of the resonator is influenced by the thickness of the piezoelectric layer and the mass of the electrode 29 and also the mass of the biochemical sample 5.

In order to prevent energy from flowing into the substrate, acoustic mirrors, which are comparable with an optical Bragg reflector, composed of a plurality of layers with alternate low and high acoustic impedance are arranged below the bottom electrode 30 of the piezoelectric element 28. With this arrangement, a quality factor Q of more than 500 relative to air is achieved for this structure. The change in the oscillator frequency is to a first approximation proportional to the change in the total mass of the sensor. Since the oscillator frequency rises inversely proportionally to the total mass, the result is a higher sensitivity for a higher resonant frequency.

However, density changes and/or viscosity changes also influence the resolution of the semiconductor chip sensor 3 on account of the same shift direction for the resulting resonator frequencies. Other influences such as the temperature and the mismatch reduce the resolution and must therefore be minimized. Such influences can be reduced in principle using further reference analysis positions that have no biochemical samples 5. Consequently, the mismatch can be subtracted, while the temperature for the reference position and hence the influence of the temperature is compensated for. What then remains as main limitation for the resolution is the thermal noise of the sensor, which principally depends on the quality factor Q, as mentioned above.

The sensor has the advantage that it is relatively insensitive to solvents for surface preparation prior to feeding the biochemical samples 5. The frequency shift caused thereby tends toward zero. The transmission of the measured values via a low-resistance through contact 7 is ensured by virtue of the fact that first of all the through contact 7 is led through active layers in its upper region, and, in the region of the semiconductor substrate 6, the low-resistance through contact 7 made of a metallically conductive material 19 is surrounded by an insulation layer 27 in order to avoid short circuits and couplings to adjacent analysis positions 4 via the semiconductor substrate 6.

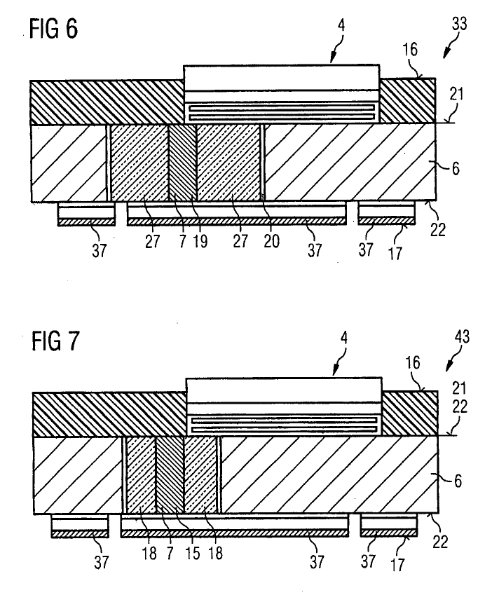

FIG. 6 shows a schematic cross section of the semiconductor sensor chip 43 of a fifth embodiment of the invention in the region of an analysis position 4. Components having the same functions as in the previous figures are identified by identical reference symbols and are not discussed separately. The electrodes 29 and 30 of the piezoelectric element 28 are led through the semiconductor substrate 6 via low-resistance through contacts 7 that were introduced into passages 20. The walls of said passages 20 are provided with an insulation layer 27, which surround the electrically conductive region made of an electrically conductive metal such as copper and therefore prevent an electrical connection to the semiconductor substrate 6.

This cross section furthermore illustrates in detail the structure of the semiconductor sensor chip 33 in the region of an analysis position 4 on the underside 22 of the semiconductor substrate 6. The through contact 7 undergoes transition to an interconnect structure that is connected to a plurality of contact areas 37 on the underside of the semiconductor chip sensor 33. The contact areas 37 may have a metallic alloy or a conductive adhesive layer. Consequently, the semiconductor sensor chip 33 can be surface-mounted on an addressing and control chip (not shown here) by its contact areas 37 arranged on the rear side 22 of the semiconductor substrate 6. The additional process outlay for the production of the low-resistance through contacts 7 in a semiconductor wafer comprises the following method steps:
1. Definition and etching of the passage 20, which may also have the form of a trench;
2. Oxidation of the sidewalls of the passage 20 with formation of an SiO₂ layer as insulation layer 27;
3. Filling of the passage 20 with metallically conductive material 19 and removal of the metal outside the passage 20;
4. Production of connections between through contact 7 and electrodes 29 and 30 of the BAW sensor and/or BAW actuator;
5. Thinning of the semiconductor wafer by grinding.

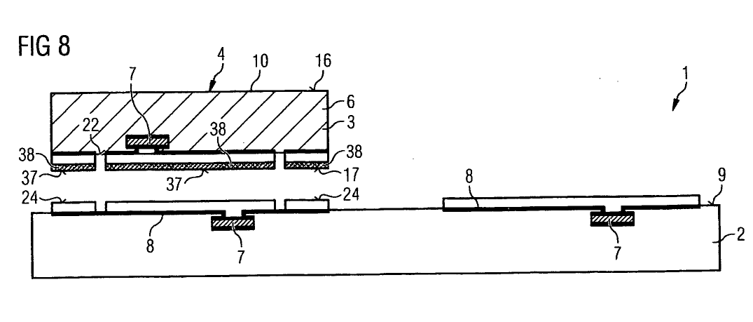

FIG. 7 shows a schematic cross section of the semiconductor sensor chip 43 of a fifth embodiment of the invention in the region of an analysis position 4. The components having the same functions as in FIG. 6 are identified by identical reference symbols and are not discussed separately. The difference between the fourth embodiment in accordance with FIG. 6 and the fifth embodiment in accordance with FIG. 7 is that rather than a metallic through contact 7 being provided in the semiconductor substrate 6, a highly doped passage region 15 is provided which has a doping that may be complementary to the doping of the semiconductor substrate 6. If the passage region 15 has the same conduction type as the semiconductor substrate 6, then a complementarily doped region 18 is additionally provided which surrounds the highly doped passage region 15.

Such a doping of the semiconductor substrate 6 can be produced by diffusion of acceptors or donors through a semiconductor wafer. The highly doped passage region 15 then has an impurity concentration of 10²⁰ cm⁻³ to 10²² cm⁻³. The additional process outlay for the production of such a low-resistance passage region 15 in a semiconductor wafer comprises the following method steps:
1. Definition and doping of the passage region 15;
2. Optimum complementary doping around the passage region 15;
3. Production of connections between passage regions 15 and electrodes 29 and 30 of the BAW sensor and/or BAW actuator;
4. Thinning of the semiconductor wafer by grinding.

FIG. 8 shows a schematic cross section through a semiconductor sensor chip 3 prior to connection to an addressing and control chip 2 to form a semiconductor chip laboratory 1. The addressing and control chip 2 has CMOS circuits. As soon as the semiconductor sensor chip 3 is placed by its contact areas 37 on the rear side 22 of the semiconductor substrate 6 of the sensor chip 3 onto the contact pads 24 of the addressing and control chip 2 and is connected to them via the electrically conductive adhesive layer 38, the two semiconductor chips are electrically connected to one another.

For this purpose, the circuit elements of the addressing and control chip 2 are electrically connected to the contact areas 37 of the semiconductor sensor chip 3 via the interconnect structure 8. The following process steps are additionally carried out for preparation of the rear side 17 of the semiconductor sensor chip 3 and the top side 9 of the addressing and control chip 2 and for the surface mounting:
1. Application of an insulation layer made of SiO₂ and/or Si₃N₄ and etching of the contact regions on the rear side 22 of the semiconductor substrate 6 or semiconductor wafer;
2. Application of contact areas 37 on the rear side 22 of the semiconductor substrate 6 or semiconductor wafer and contact definition;
3. Preparation of the contact areas 37 of the semiconductor sensor chip 3 and of the contact pads 24 of the addressing and control chip 2 with conductive adhesive or metal layers for the later formation of an alloy after the formation of the connections and subsequent removal of unnecessary regions outside the contact areas 37 and the contact pads 24;
4. Positioning of the semiconductor sensor chip 3 with FBAR structure 10 on the addressing and control chip 2 with CMOS circuits;
5. Heating of the positioned semiconductor chips 2 and 3 in a furnace for the formation of a conductive mechanically stable connection between the contact areas 37 and the contact pads 24.

The top side 9 of the addressing and control chip 2 has a larger areal extent than the top side 16 of the semiconductor sensor chip, so that the addressing and control chip 2 simultaneously forms the circuit carrier for the semiconductor sensor chip. Although only one individual analysis position 4 is shown symbolically in this illustration in FIG. 8, in reality the top side 16 of the semiconductor sensor chip 3 has a multiplicity of such analysis positions 4 which are connected to the addressing and control chip 2. In this case, the addressing and control chip 2 serves for detecting the differences in the resonant frequency of the piezoelectric elements in the analysis positions 4. This involves detecting whether biochemical samples have reacted with indicator molecules of corresponding analysis solutions and thus their viscosity, their mass and/or their density have changed or not changed.

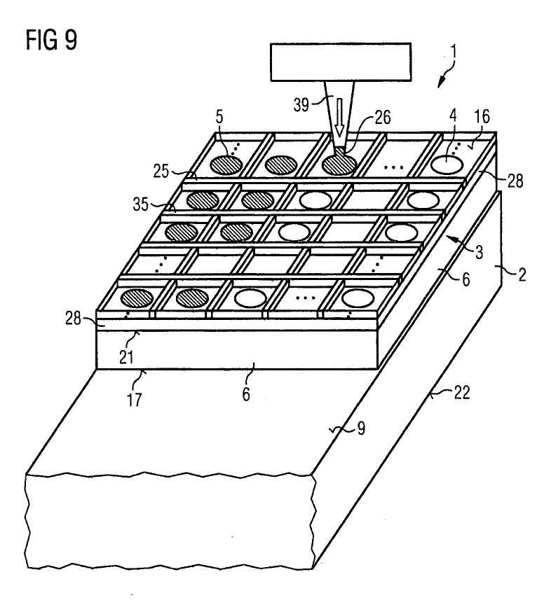

FIG. 9 shows a perspective basic schematic diagram of a semiconductor chip laboratory 1 of a first embodiment of the invention. On the semiconductor sensor chip 3, dots indicate that any desired number of analysis positions 4 can be arranged on the top side 16 of the semiconductor sensor chip 3. Firstly, biochemical samples 5 are applied to the analysis positions 4 by way of a pipette 39. After evaporation of the solvent, the molecules of the biochemical samples 5, such as DNA sequences for example, adhere to the analysis positions. By way of a further pipette 39, an analysis solution 26 is subsequently applied either to individual or to all biochemical samples 5, said analysis solution having indicator molecules which can dock to the molecules of the biochemical samples 5.

The fact of whether the biochemical samples 5 have reacted with the indicator molecules of the analysis solution 26 can be established by the change in the resonant frequency of the piezoelectric elements 28 in the analysis positions 4. For this purpose, the signals are conducted to corresponding CMOS circuits of the addressing and control chip 2 via low-resistance through contacts (not shown here) through the semiconductor substrate 6 of the semiconductor sensor chip 3. Since the connections for the individual analysis positions 4 are effected via the rear side 17 of the semiconductor sensor chip 3, the analysis positions 4 of the top side 16 of the semiconductor sensor chip 3 can be accessed freely. The construction of a semiconductor chip laboratory 1 that is shown in FIG. 9 can be cast into a plastic housing composition 25 whilst leaving free the analysis positions 4, for the protection of the CMOS circuits. In order to demarcate the analysis positions 4 from neighboring positions, the semiconductor chip laboratory 1 has compartmentalizing elements 35 in the form of a grid-shaped frame composed of a plastic housing composition 25.

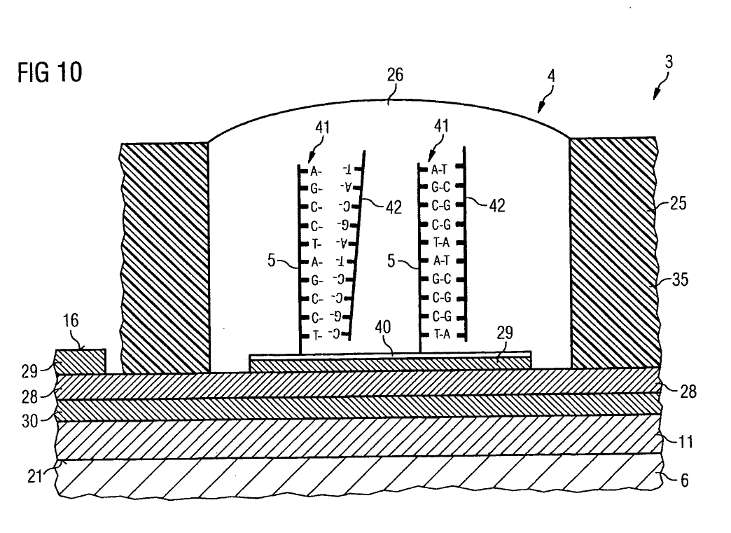

FIG. 10 shows a schematic cross section through an analysis position 4 with applied analysis solution 26. Said analysis solution 26 fully fills the analysis position 4 and covers the top electrode 29 of the piezoelectric element 28 made of an aluminum-nickel layer. The top electrode 29 has a coating 40 made of silicon nitride, which brings about an anchoring of the biochemical samples 5 on the electrode 29. In this embodiment of the invention, the biochemical sample 5 comprises DNA sequences attached as molecules to the coating 40.

The analysis solution 26 contains indicator molecules 42 which can dock to the DNA sequence 41 if they match said sequence 41, as is shown in the right-hand example in FIG. 10. The indicator molecules 42 do not dock if the indicator molecules 42 have a sequence that does not match the DNA sequence 41. Afterward, the analysis solution 26 is removed, and the molecules of the biochemical sample 5 and the docked molecules remain on the piezoelectric element 28 or on the coating 40, which leads to a change in the resonant frequency. If, by contrast, no molecules are docked, then practically the resonator frequency as was measured previously remains unchanged. If a corresponding large number of indicator molecules 42 have docked to the sample molecules 41, then there is a change in the mass on the top electrode 29 and the resonator frequency is therefore shifted, which can be detected by the coupled CMOS circuits of the addressing and control chip 2. The compartmentalizing elements 35 surround each of the analysis positions 4 and ensure that the analysis solution 26 can be delivered to one of the analysis positions 4 in a targeted manner.

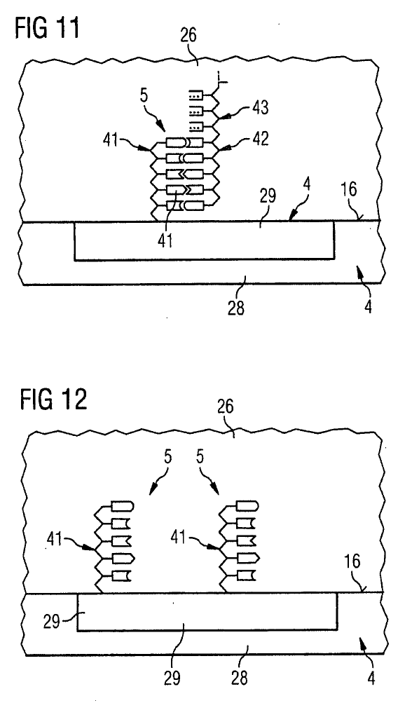

FIGS. 11 to 17 show individual examples of the docking and non-docking of indicator molecules to sample molecules.

FIG. 11 shows a basic schematic diagram with docking of an indicator molecule 42 to a DNA sequence 41. The indicator molecule 42 can have additional indicator sequences 43 that increase the mass proportion, so that a higher selectivity can be achieved with such indicator molecules 42 on account of the increased mass. On the other hand, the additional indicator sequences 43 can have particular optical properties that are utilized to further support the measurement results.

FIG. 12 shows a basic schematic diagram of provision of a DNA sample 5 to be analyzed. Only two molecules of a DNA sequence 41 are shown here, which are anchored on the top electrode 29 of the piezoelectric element 28. However, a multiplicity of such molecules of identical DNA sequences 41 can be arranged as biochemical sample 5 on the top electrode 29 of the piezoelectric element 28. The composition of the analysis solution 26 will now be varied in the subsequent examples.

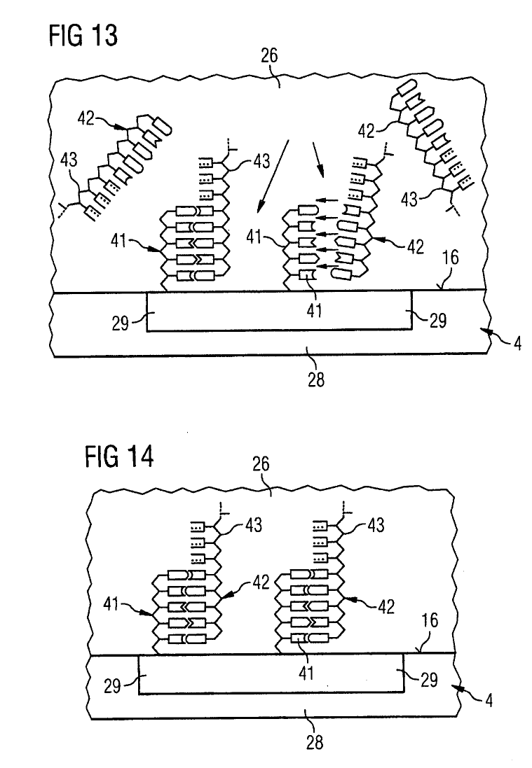

FIG. 13 shows a basic schematic diagram of docking of a DNA indicator on an analysis position 4 to a DNA sequence 41. In the left-hand case, the indicator molecules 42 arranged in the analysis solution 26 are docked to the DNA sequence 41, while in the case shown on the right, the second indicator molecules 42 contained in the analysis solution 26 do not match the DNA sequence 41 and consequently remain in the solution 26 and are rinsed away with the solution 26 during the subsequent rinsing process, so that only one of the two indicator molecule types 42 is accepted.

FIG. 14 shows a basic schematic diagram of docking of a DNA indicator of an analysis position 4 to DNA samples. In this case, a plurality of DNA sequences 41 of identical type are equally provided with corresponding indicator molecules 42, so that the mass, the viscosity and/or the density of the biochemical sample 5 on the top electrode 29 of the piezoelectric element 28 increases in such a way as to produce a measurable resonant frequency difference Δf.

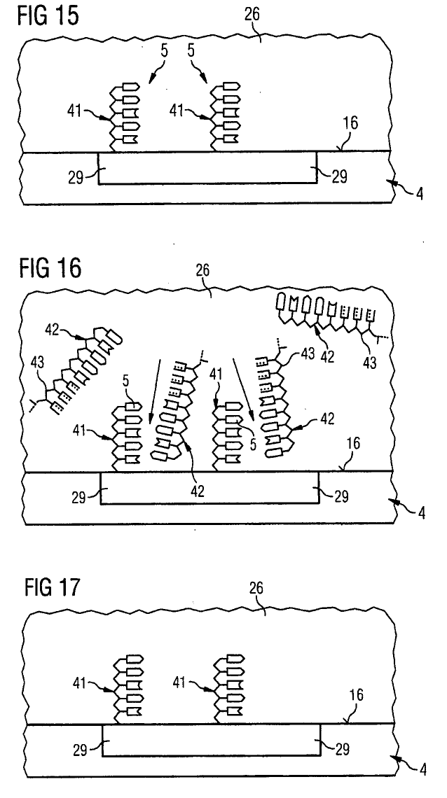

FIG. 15 shows a basic schematic diagram of provision of DNA samples 5 to be analyzed on an analysis position 4. This provision is carried out by applying a biochemical sample 5 to the analysis position 4, said sample 5 in the form of DNA sequences 41 remaining on the coated top side of the top electrode 29.

As long as only rinsing solutions are applied as analysis solution 26, or solutions which have exactly these DNA sequences 41, these DNA sequences 41 continue on the electrodes 29 and the solvent of the analysis solution 26 can be evaporated or rinsed off in order to leave a highly viscous or solid biochemical sample 5 on the top side 16 of the analysis position 4. Afterward, a further analysis solution 26 with corresponding indicator molecules is applied to the top side 16 of the semiconductor sensor chip and, depending on the type of indicator molecules arranged therein, the docking possibilities thereof are analyzed.

In the case of FIG. 16, it emerges that none of the indicator molecules 42 matches the DNA sequence 41. The indicator molecules 42 are therefore rinsed away with the solvent of the analysis solution 16.

As the result, FIG. 17 shows a basic schematic diagram of a non-marked DNA sample 5 on an analysis position 4. In this case, the indicator molecules in the analysis solution 26 have not marked the DNA sequences 41, so that the same resonator frequency as with the original biochemical sample 5 results after the removal of the analysis solution 26.

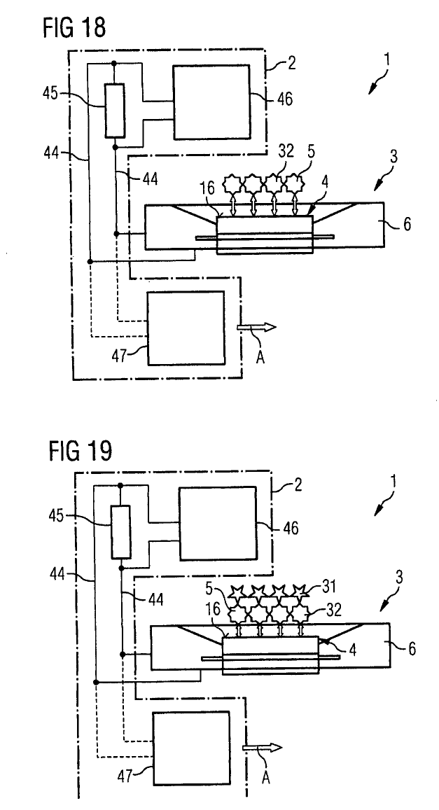

FIG. 18 shows a basic schematic diagram of a semiconductor chip laboratory 1 after taking up a biochemical sample 5 with circuits of the addressing and control chip 2. In this case, the biochemical semiconductor chip laboratory 1 corresponds to the examples discussed above. In the analysis positions 4, biochemical molecules 32 are arranged on the top side 16 of the semiconductor sensor chip 3, wherein the circuits of the addressing and control chip 2 arranged below the sensor chip 3 are marked schematically by a dashed-dotted line, and the CMOS circuits are subdivided into blocks 46 and 47.

The block 47 represents a frequency generator, which has an inductance 45 in parallel with the output, and which is connected via interconnects 44 on the one hand to the semiconductor sensor chip 3 and on the other hand to a detector circuit 47 for amplitude and phase of the output signals, which are forwarded from the addressing and control chip 2 in arrow direction A.

FIG. 19 shows a basic schematic diagram of a semiconductor chip laboratory 1 after docking of analysis molecules 31 to the biochemical molecules 32. After the docking of the analysis molecules 31 to the biochemical molecules 32, there is a change in the mass, and/or the viscosity and/or the density of the biochemical sample material on the top side 16 of the semiconductor sensor chip 3 in the individual analysis positions 4, which in turn results in a resonator frequency change that is output by the detector circuit 47 in arrow direction A.

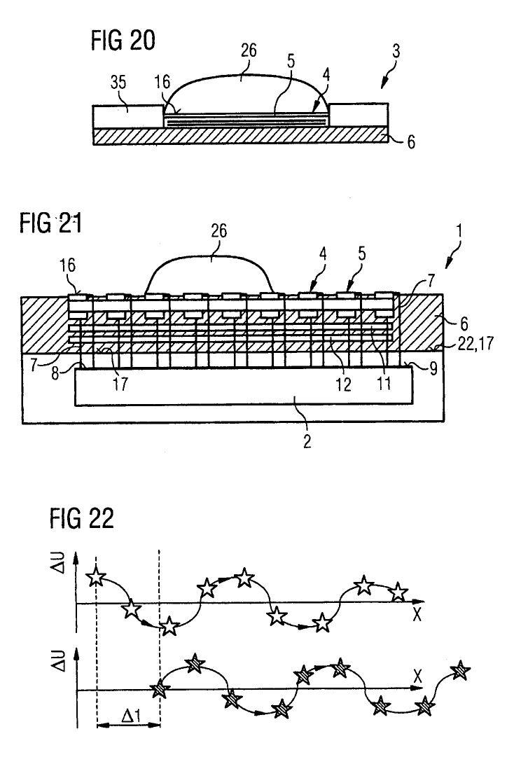

FIG. 20 shows a basic schematic diagram of the application of an analysis solution 26 to an analysis position 4 of a semiconductor sensor chip 3. The propagation of the analysis solution 26 is delimited by compartmentalizing elements 35, so that individual analysis positions 4 can be supplied with the analysis solution 26.

FIG. 21 shows a basic schematic diagram of the application of an analysis solution 26 to a plurality of analysis positions 4. In this embodiment of the invention, the individual analysis positions 4 of the biochemical semiconductor chip laboratory 1 are not delimited by compartmentalizing elements, so that the analysis solution 26 can propagate over all the analysis positions 4 of the semiconductor sensor chip 3. Each of the analysis positions 4 is connected via through contacts 7 to the addressing and control chip 2, which has CMOS circuits in order to detect resonator frequency differences. In this case, the addressing and control chip 2 may have shift registers which, at time and length intervals of Δl, switch through the detection of the measured values from one analysis position 4 to the next analysis position, as is shown in FIG. 22.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A biochemical semiconductor chip laboratory, comprising:
a coupled addressing and control chip for biochemical analyse; and
a semiconductor sensor chip including a multiplicity of analysis positions for biochemical samples in a matrix on a semiconductor substrate, arranged on the addressing and control chip, the analysis positions being electrically connected to an interconnect structure on the top side of the addressing and control chip via low-resistance through contacts through the semiconductor substrate.

2. The semiconductor chip laboratory as claimed in claim 1,
wherein
the semiconductor sensor chip converts mass, viscosity and density changes of biochemical samples into resonant frequency changes.

3. The semiconductor chip laboratory as claimed in claim 1, wherein
the semiconductor sensor chip in the analysis positions on the semiconductor substrate, includes FBAR resonators (film bulk acoustic resonators) which transmit resonant frequency changes in the gigahertz range to the addressing and control chip via the low-resistance through contacts in the semiconductor sensor chip.

4. The semiconductor chip laboratory as claimed in claim 3, wherein the FBAR resonators include piezoelectric elements having BAW resonant frequencies in the gigahertz range.

5. The semiconductor chip laboratory as claimed in claim 3, wherein
a plurality of reflector layers for BAW waves, which alternately have layers of high impedance and layers of low impedance, are arranged below the piezoelectric elements.

6. The semiconductor chip laboratory as claimed in claim 3, wherein a cavity for the decoupling of BAW waves is arranged between the piezoelectric elements and the semiconductor substrate.

7. The semiconductor chip laboratory as claimed in claim 1, wherein the addressing and control chip includes circuits based on complementary MOS transistors for taking up, assigning and evaluating resonant frequency changes in the gigahertz range.

8. The semiconductor chip laboratory as claimed in claim 1, wherein low-resistance through contacts include highly doped passage regions through the thickness of the semiconductor substrate from the top side to the rear side of the semiconductor sensor chip in the analysis positions.

9. The semiconductor chip laboratory as claimed in claim 8, wherein the highly doped passage regions are surrounded by complementarily doped regions of the semiconductor substrate.

10. The semiconductor chip laboratory as claimed in claim 1, wherein the low-resistance through contacts include a metallically conductive material arranged in passages from the top side to the rear side of the semiconductor substrate in the analysis position.

11. A method for producing a biochemical semiconductor chip laboratory including a semiconductor sensor chip and an addressing and control chip, the method comprising:
producing low-resistance through contacts from the top side of a semiconductor substrate to the rear side of the semiconductor substrate in provided analysis positions of a semiconductor sensor chip;
applying a multiplicity of analysis positions for biochemical samples in a matrix on the semiconductor substrate with formation of a semiconductor sensor chip;
producing an addressing and control chip with an interconnect structure on its top side with contact pads for low-resistance through contacts of a semiconductor sensor chip;
applying the semiconductor sensor chip by its surface-mountable low-resistance through contacts onto the contact pads of the interconnect structure of the addressing and control chip; and
embedding the semiconductor chip laboratory into a plastic housing composition whilst leaving free the analysis positions of the semiconductor sensor chip.

12. The method as claimed in claim 11, wherein, in order to produce low-resistance through contacts in provided analysis positions of a semiconductor sensor chip through the thickness of the semiconductor substrate from the top side of a semiconductor substrate to the rear side of the semiconductor substrate, high doping is effected complementarily to the conduction type of the semiconductor substrate.

13. The method as claimed in claim 11, wherein, in order to produce low-resistance through contacts in provided analysis positions of a semiconductor sensor chip through the thickness of the semiconductor substrate from the top side of the semiconductor substrate to the rear side of the semiconductor substrate, a passage is filled with metallically conductive material.

14. A method for biochemical analysis using a semiconductor chip laboratory including a coupled addressing and control chip for biochemical analyses and a semiconductor sensor chip including a multiplicity of analysis positions for biochemical samples in a matrix on a semiconductor substrate, arranged on the addressing and control chip, the analysis positions being electrically connected to an interconnect structure on the top side of the addressing and control chip via low-resistance through contacts through the semiconductor substrate, the method comprising:
applying biochemical samples on the analysis positions;
determining a first resonant frequency in the analysis positions and storage of the first-resonant frequency under the addresses of the addressing and control chip;
applying an analysis solution to the biochemical samples in the analysis positions;
removing the analysis solution with reaction products being left behind;
determining a second resonant frequency in the analysis positions and storage of the second resonant frequency under the addresses of the addressing and control chip;
determining the differences between the first and second resonant frequencies and evaluation of the resonant frequency differences in order to determine at least one of mass and density changes of the biochemical samples.

15. The method as claimed in claim 14, wherein analysis positions are covered with at least one of comparison and calibration samples.

16. The semiconductor chip laboratory as claimed in claim 2, wherein the semiconductor sensor chip, in the analysis positions on the semiconductor substrate, includes FBAR resonators (film bulk acoustic resonators) which transmit resonant frequency changes in the gigahertz range to the addressing and control chip via the low-resistance through contacts in the semiconductor sensor chip.

17. The semiconductor chip laboratory as claimed in claim 4, wherein a plurality of reflector layers for BAW waves, which alternately have layers of high impedance and layers of low impedance, are arranged below the piezoelectric elements.

18. The semiconductor chip laboratory as claimed in claim 4, wherein a cavity for the decoupling of BAW waves is arranged between the piezoelectric elements and the semiconductor substrate.

19. The semiconductor chip laboratory as claimed in claim 5, wherein a cavity for the decoupling of BAW waves is arranged between the piezoelectric elements and the semiconductor substrate.
